(19) United States
(12) Patent Application Publication
(10) Pub. No.: US 2025/0306311 A1
(43) Pub. Date: Oct. 2, 2025

(54) SEMICONDUCTOR DEVICE AND METHOD FOR MANUFACTURING THE SAME

(71) Applicant: TAIWAN SEMICONDUCTOR MANUFACTURING COMPANY LTD., HSINCHU (TW)

(72) Inventors: FENG YUAN, HSINCHU CITY (TW); WEN-SHUN LO, HSINCHU COUNTY (TW); CHI-YUAN SHIH, HSINCHU (TW); YINGKIT FELIX TSUI, CUPERTINO, CA (US); SHIH-FEN HUANG, HSINCHU COUNTY (TW)

(21) Appl. No.: 18/617,650

(22) Filed: Mar. 27, 2024

(51) Int. Cl. G02B 6/42; H01L 21/48; H01L 23/34

(52) U.S. Cl. CPC G02B 6/4266; H01L 23/345; H01L 21/4814

(57) ABSTRACT

A semiconductor device and a method of manufacturing the same are provided. The semiconductor device includes a semiconductor substrate; a first dielectric layer; a second dielectric layer; a waveguide; a heater; a first conductive layer; a conductive contact; and a second conductive layer. The first dielectric layer is disposed on the semiconductor substrate. The second dielectric layer is disposed on the first dielectric layer. The waveguide is disposed in the first dielectric layer. The heater is disposed in the second dielectric layer and above the waveguide. The first conductive layer comprises a plurality of first conductive interconnects disposed above the heater. The conductive contact is electrically connected to the heater and disposed between the heater and the first conductive layer. The second conductive layer comprises a plurality of second dummy interconnects.

### TECHNICAL FIELD

The present disclosure relates, in general, to semiconductor devices and methods for manufacturing the same. Specifically, the present disclosure relates to semiconductor devices with dummy metal layers varying thermal conductivity around a metal heater and method for manufacturing the same.

### BACKGROUND

A semiconductor structure can include multiple optical elements providing optical links for data communication. In recent years, advances in information technologies, such as Big Data, cloud computation, cloud storage, and Internet of Things, have driven exponential growth of data communications in high performance computers, data centers, and long-haul telecommunication. Silicon photonics may be used to provide a fast on-chip and off-chip optical link for data communication at low cost and high energy efficiency.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1a is a diagram of a semiconductor device from a top view in accordance with some embodiments of the present disclosure.

FIG. 1b is a cross section of the semiconductor device along line 1b-1b′ of FIG. 1a.

FIG. 1c is a cross section of the semiconductor device along line 1c-1c′ of FIG. 1a.

FIG. 2a is a diagram of a semiconductor device from a top view in accordance with some embodiments of the present disclosure.

FIG. 2b is a cross section of the semiconductor device along line 2b-2b′ of FIG. 2a.

FIG. 2c is a cross section of the semiconductor device along line 2a-2a′ of FIG. 2a.

FIG. 3a is a diagram of a semiconductor device from a top view in accordance with some embodiments of the present disclosure.

FIG. 3b is a diagram of a semiconductor device from a top view in accordance with some embodiments of the present disclosure.

FIG. 3c is a diagram of a semiconductor device from a top view in accordance with some embodiments of the present disclosure.

FIG. 3d is a diagram of a semiconductor device from a top view in accordance with some embodiments of the present disclosure.

FIGS. 4a, 4b, and 4c illustrate a method for manufacturing the semiconductor device shown in FIG. 1, in accordance with some embodiments of the present disclosure.

FIGS. 5a, 5b, and 5c illustrate a method for manufacturing the semiconductor device shown in FIG. 2a, in accordance with some embodiments of the present disclosure.

FIG. 6 is a diagram of a semiconductor device in accordance with some embodiments of the present disclosure.

FIGS. 7a, 7b, 7c, 7d, 7e, 7f, 7g, 7h, 7i, 7j, and 7k illustrate a method for manufacturing a semiconductor device, in accordance with some embodiments of the present disclosure.

FIG. 8 is a diagram of a semiconductor device in accordance with some embodiments of the present disclosure.

FIGS. 9a, 9b, 9c, 9d, 9e, 9f, 9g, 9h, 9i, and 9j illustrate a method for manufacturing a semiconductor device in accordance with some embodiments of the present disclosure.

FIG. 10 is a flowchart of an embodiment of a method of manufacturing a semiconductor device in accordance with some embodiments of the present disclosure.

FIG. 11 is a flowchart of an embodiment of a method of manufacturing a semiconductor device in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a method for controlling metal heater thermal efficiency and thermal response time constant in silicon photonic devices. The method uses a back-end-of-the-line (BEOL) process to form a dummy metal layer to vary the thermal conductivity proximate to the metal heater.

Some exemplary operations of formation of optical elements, the heater, and the dummy metal layer are disclosed as follows. Exemplary operations for formation of the dummy interconnects (dummy contacts or dummy layer) may be formed by known processes in the dielectric layer to achieve a desired uniformity of the metal and dielectric distribution, thereby increasing the device yield and strength, adjusting a thermal response of the semiconductor device, and controlling metal heater thermal efficiency. The metal heater thermal efficiency refers to the time required to increase the temperature of optical components, such as a waveguide, to a desired temperature through heating operations. The shorter the time required to reach the desired temperature, the better the thermal efficiency. If the time for heating the waveguide to reach a desired high temperature is short, then the thermal efficiency is high. In contrast, if the time required to reach the desired temperature is longer, then the thermal efficiency is poorer or lower. Thermal response refers to the time required for an optical component, such as a waveguide, to decrease from a higher temperature to a desired lower temperature. The shorter the time required to reach the desired lower temperature, the shorter the thermal response time. When the heating operation is stopped, if the time needed for the waveguide to reach a desired lower temperature is short, then the thermal response is short or small. In contrast, if the time required to reach the desired lower temperature is longer, the thermal response time is longer or greater.

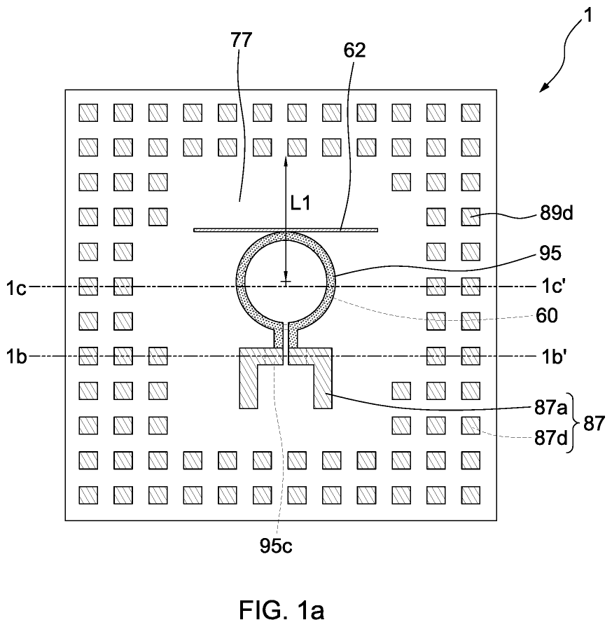

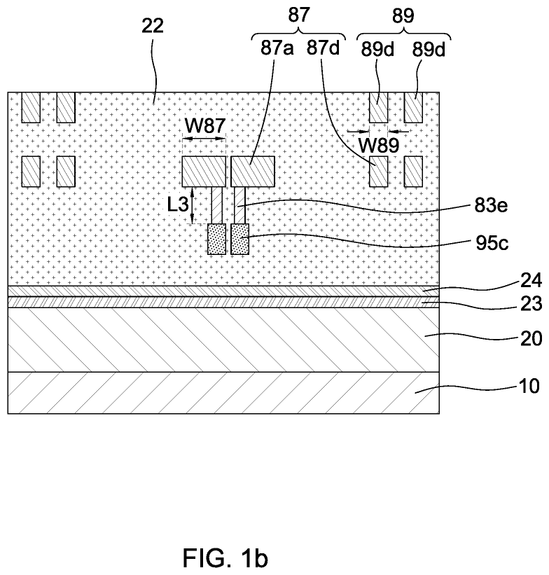

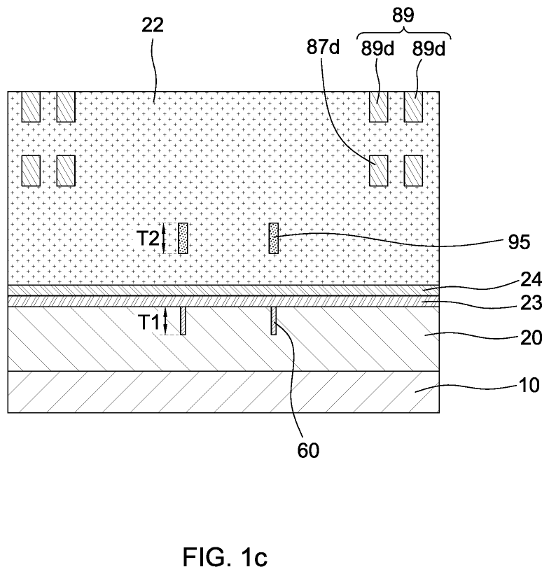

FIG. 1a is a diagram of a semiconductor device 1 from a top view in accordance with some embodiments of the present disclosure. FIG. 1a shows a semiconductor device 1. FIG. 1b is a cross section of the semiconductor device 1 along line 1b-1b′ of FIG. 1a. FIG. 1c is a cross section of the semiconductor device 1 along line 1c-1c′ of FIG. 1a.

Referring to FIG. 1a, the semiconductor device 1 includes a semiconductor substrate 10, a first dielectric layer 20, dielectric layers 23 and 24, a second dielectric layer 22, a ring shape waveguide 60 (or an annular waveguide 60), a strip waveguide 62, a heater 95, a first conductive layer 87, and a second conductive layer 89. In the semiconductor substrate 10 as shown, some features have been omitted for simplification. For example, the semiconductor substrate 10 may include CMOS transistors or other electric components such as resistors, diodes etc. In some embodiments, the semiconductor substrate 10 includes several materials such as silicon, GaAs, germanium, silicon on insulator (SOI) or other suitable semiconductive materials.

Referring to FIG. 1b, the first dielectric layer 20 is disposed on the semiconductor substrate 10. The second dielectric layer 22 is disposed on the first dielectric layer 20. The waveguide 60 is disposed in the first dielectric layer 20. In some embodiments, the dielectric layer 23 includes dielectric materials such as SiO₂, SiN, SiCOH, a spin-on low-k dielectric material, or other suitable materials. In some embodiments, the fourth dielectric layer 24 includes dielectric materials such as SiN, or other suitable materials. In some embodiments, the perpendicular length L3 of the conductive contact 83e ranges from approximately 3000 Ångstrom (Å) to 15000 Å.

Referring to FIG. 1c, the heater 95 is disposed in the second dielectric layer 22 and above the waveguide 60. The thickness T1 of the waveguide 60 ranges from approximately 200 nm to 240 nm. In some embodiments, the thickness of the waveguide 62 is similar to the thickness of the waveguide 60. In some embodiments, a ring shape heater 95 (or an annular heater 95) is disposed in the second dielectric layer 22 and directly above the annular waveguide 60. Therefore, in the top view as shown in FIG. 1a, the heater overlaps with the waveguide 60. In some embodiments, the heater 95 includes tungsten (W). In some embodiments, the heater 95 can include nichrome, FeCrAl, Cupronickel (CuNi), or any other suitable materials. The first conductive layer 87 comprises a plurality of first conductive interconnects 87a disposed above the heater 95. A conductive contact 83e is electrically connected to the heater 95 and disposed between the heater 95 and the first conductive layer 87. The heater 95 is configured to adjust the frequency of the light passing through the waveguides 60 and 62 by increasing the temperature. The heater 95 is usually utilized in silicon photonics in use of the thermo-optic effects of Si to manipulate the photons within the waveguide (e.g., the function of the heater 95 stabilizes a micro-ring resonator). A distance between a bottom surface of the heater 95 and a top surface of the fourth dielectric layer 24 ranges from approximately 3000 Å to 12000 Å. The thickness T2 of the heater 95 ranges from approximately 1500 Å to 3000 Å.

A strip waveguide 62 is disposed in the first dielectric layer 20 and adjacent to the annular waveguide 60. In some embodiments, the strip waveguide 62 can be in contact with the annular waveguide 60. In other embodiments, a gap may exist between the strip waveguide 62 and the annular waveguide 60. The first dielectric layer 20 can be formed by various processes, such as chemical vapor deposition (CVD) or spin-coating. The first dielectric layer 20 covers the semiconductor substrate 10 and provides electrical insulation between the semiconductor substrate 10 and overlaid conductive features. The first dielectric layer 20 is disposed on the semiconductor substrate 10. The dielectric layer 20 covers a top surface 101 of the semiconductor substrate 10. The dielectric layer 20 includes dielectric materials such as silicon oxide (SiO₂), silicon nitride (SiN), SiCOH, a spin-on low-k dielectric material such as SiLK™, etc, or other suitable materials. In some embodiments, the thickness of the first dielectric layer 20 ranges from approximately 1.5 micrometers (μm) to 2 μm. The dielectric layer 22 is disposed on the fourth dielectric layer 24. The dielectric layer 22 includes dielectric materials such as SiO₂, SiN, SiCOH, a spin-on low-k dielectric material such as SiLK™, etc, or other suitable materials. In some embodiments, the dielectric layer 22 includes SiO₂.

In some embodiments, the second conductive layer 89 comprises a plurality of second dummy interconnects 89d disposed above the first conductive layer 87. The dummy interconnects 89d (or dummy contacts) may be formed by known processes in the dielectric layer to achieve a desired uniformity of the metal and dielectric distribution, thereby increasing the device yield and strength, adjusting a thermal response of the semiconductor device 1, and controlling metal heater thermal efficiency. In some embodiments, the second dummy interconnects 89d disposed in the dielectric layer do not electrically connect to any component or are not used as a contact.

Referring back to FIG. 1a, the heater 95 is annular from a top view and the second conductive layer 89 includes a clearance zone 77 above the heater 95 from a top view. No second dummy interconnect 89d is disposed in the clearance zone 77 from the top view. In some embodiments, no dummy interconnect 87d is disposed in the clearance zone 77 from the top view. In some embodiments, no first conductive interconnect 87a is disposed in the clearance zone 77 from the top view. A distribution density of the second conductive layer 89 (comprising dummy interconnects 89d) directly disposed above the heater 95 from the top view may be adjusted based on parameters of metal heater thermal efficiency and thermal response time constant of the semiconductor device 1. Distribution density of the dummy interconnect 87d directly disposed above the heater 95 from the top view may be adjusted based on parameters of metal heater thermal efficiency and a thermal response time constant of the semiconductor device 1.

In some embodiments, the waveguide 60 comprises a ring shape being aligned with the ring shape of the heater 95 from the top view. In some embodiments, the annular waveguide 60 is aligned with the annular heater 95 from the top view. A vertical projection of the annular of the heater 95 falls on a vertical projection of the second annular waveguide 60. A vertical projection of the annular of the heater 95 falls on the second annular waveguide 60. In some embodiments, an area of a vertical projection of the annular of the heater 95 is greater than an area of a vertical projection of the annular waveguide 60. In some embodiments, an area of a vertical projection of the annular of the heater 95 is equal to an area of a vertical projection of the annular waveguide 60.

From the top view, a minimum distance L1 between a second dummy interconnect 89d and a geometric center of the annular of the heater 95 is about 15 μm to 35 μm. The conductive contact 83e is electrically connected to one of the plurality of first conductive interconnects 87a. The conductive contact 83e is used to supply voltage to the heater 95. The conductive contact 83e includes tungsten or other suitable material.

In some embodiments, the first conductive layer 87 comprises a plurality of first dummy interconnects 87d. Referring to FIGS. 1a and 1b, each of the plurality of second dummy interconnects 89d is aligned with each of the plurality of first dummy interconnects 87d from the top view. An area of a vertical projection of one of the second dummy interconnects 89d is equal to an area of a vertical projection of one of the first dummy interconnects 87d.

No second dummy interconnect 89d is directly disposed above the plurality of first conductive interconnects 87a from the top view. No second dummy interconnect 89d is directly disposed above the heater 95 and waveguide 60. No first dummy interconnects 87d are directly disposed above the heater 95 and waveguide 60.

In some embodiments, a lateral width W87 of one of the plurality of first conductive interconnects 87a is greater than a lateral width W89 of one of the plurality of second dummy interconnects 89d. The lateral width of one of the plurality of first conductive interconnects 87a is greater than a lateral width of one of the plurality of first dummy interconnects 87d. The heater 95 comprises a conductive pad 95c. A lateral width of the conductive contact 83e is less than a lateral width of one of the plurality of first conductive interconnects 87a and a lateral width of the conductive pad 95c.

The conductive contacts 83e are electrically connected to one of the plurality of first conductive interconnects 87a and to the heater 95. The conductive contacts 83e can include a material identical to that of the heater 95. The plurality of first conductive interconnects 87a and dummy interconnects 87d can include a material different from that of the heater 95. In some embodiments, the plurality of first conductive interconnects 87a and dummy interconnects 87d include material such as copper (Cu) or other suitable metals.

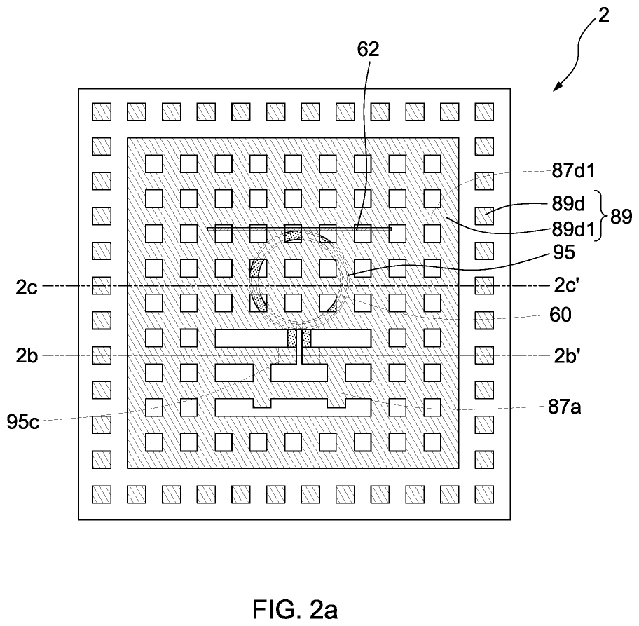

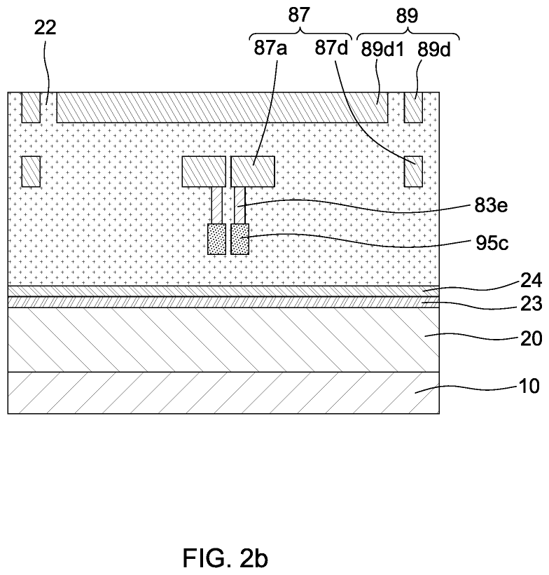

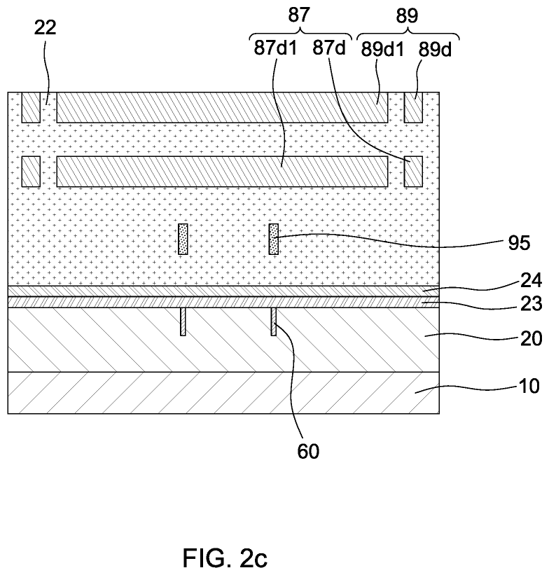

FIG. 2a is a diagram of a semiconductor device 2 from a top view in accordance with some embodiments of the present disclosure. FIG. 2a shows a semiconductor device 2. FIG. 2b is a cross section of the semiconductor device 2 along line 2b-2b′ of FIG. 2a. FIG. 2c is a cross section of the semiconductor device 2 along line 2a-2a′ of FIG. 2a.

In some embodiments, a second conductive layer 89 comprises a plurality of second dummy interconnects 89d disposed above the first conductive layer 87. A plurality of second dummy interconnects 89d is disposed above a plurality of first dummy interconnects 87d. In some embodiments, a second conductive layer 89 comprises a plurality of dummy interconnects 89d and a plurality of dummy interconnects 89d1. In some embodiments, a first conductive layer 87 comprises a plurality of dummy interconnects 87d and a plurality of conductive interconnects 87a. In some embodiments, each of the plurality of dummy interconnects 89d is aligned with each of the plurality of first dummy interconnects 87d from the top view. In some embodiments, one of the plurality of dummy interconnects 89dl is disposed above the conductive interconnects 87a (for example, see FIG. 2b). In some embodiments, one of the plurality of dummy interconnects 89d1 is disposed above one of the plurality of dummy interconnects 87d1. In some embodiments, an area of a vertical projection of one of the dummy interconnects 89d1 is equal to an area of a vertical projection of one of the dummy interconnects 87d1 (for example, see FIG. 2c). In some embodiments, a vertical projection of one of the dummy interconnects 89d1 is aligned with a vertical projection of one of the dummy interconnects 87d1.

A vertical projection of one of the plurality of second dummy interconnects 89d1 falls on a vertical projection of one of the plurality of first conductive interconnects 87a. A lateral width of one of the plurality of first conductive interconnects 87a is greater than a lateral width of one of the conductive contacts 83e. An area of a vertical projection of one of the second dummy interconnects 89d is equal to an area of a vertical projection of one of the first dummy interconnects 87d. An area of a vertical projection of the dummy interconnects 89d1 is equal to an area of a vertical projection of the dummy interconnects 87d1. An area of a vertical projection of one of the dummy interconnects 89d1 is equal to an area of a vertical projection of one of the dummy interconnects 87d1.

The annular waveguide 60 is aligned with the annular heater 95 from the top view. A vertical projection of the second conductive layer 89 falls on a vertical projection a strip waveguide 62. In some embodiments, a vertical projection of the second conductive layer 89 falls on a portion of a strip waveguide 62. No second conductive layer 89 is disposed above the other portion of the strip waveguide 62 from the top view. A vertical projection of the second conductive layer 89 falls on a vertical projection of the annular heater 95. In some embodiments, a vertical projection of the second conductive layer 89 falls on a portion of e annular heater 95. No second conductive layer 89 is disposed above the other portion of the annular heater 95 from the top view.

The conductive contact 83e is electrically connected to the annular heater 95 and vertically disposed between the annular heater 95 and the first conductive layer 87 in a cross section of the semiconductor device 2. The first conductive layer 87 comprises a plurality of first dummy interconnects 87d. One of the plurality of first dummy interconnects 87d is aligned with a corresponding one of the plurality of second dummy interconnects 89d from a top view. An area of a vertical protection of one of the plurality of first dummy interconnects 87d is aligned with an area of a vertical protection of a corresponding one of the plurality of second dummy interconnects 89d from a top view. Compared with semiconductor devices 1 and 2, dummy metals are placed on top of a metal heater 95 of the semiconductor device 2 to reduce thermal conductivity in its surroundings, resulting in improved heater thermal efficiency and longer thermal response time constant. When connected dummy metals are arranged above the metal heater 95 of the semiconductor device 2, they enhance the thermal conductivity in its environment, leading to lower heater thermal efficiency and shorter thermal response time constant, thereby increasing thermal responsivity. Compared with the semiconductor devices 1 and 2, a time required for increasing the temperature of the semiconductor device 1 is shorter than a time required for increasing the temperature of the semiconductor device 2. In contrast, semiconductor device 1 dissipating heat and reducing the temperature is slower than semiconductor device 2. A time required for semiconductor device 1 to dissipate heat and reduce the temperature is longer than a time required for semiconductor device 2 to dissipate heat and reduce temperature. Distribution density of the dummy interconnects 87d and 89d directly disposed above the heater 95 from the top view can be adjusted to optimize a trade-off between the thermal efficiency and the thermal response time of the semiconductor device 1 and 2. Using connected dummy metals above the metal heater 95 can enhance thermal conductivity, while removing dummy metals from the top of the metal heater 95 can decrease thermal conductivity. This allows control of thermal efficiency and thermal response time constant of the metal heater 95 in silicon photonic devices, depending on the specific requirements and applications.

Semiconductor device 1 has higher heater thermal efficiency and longer thermal response time than semiconductor device 2. Dummy metal density can be adjusted above the metal heater 95 to manipulate metal heater thermal efficiency and thermal responsivity.

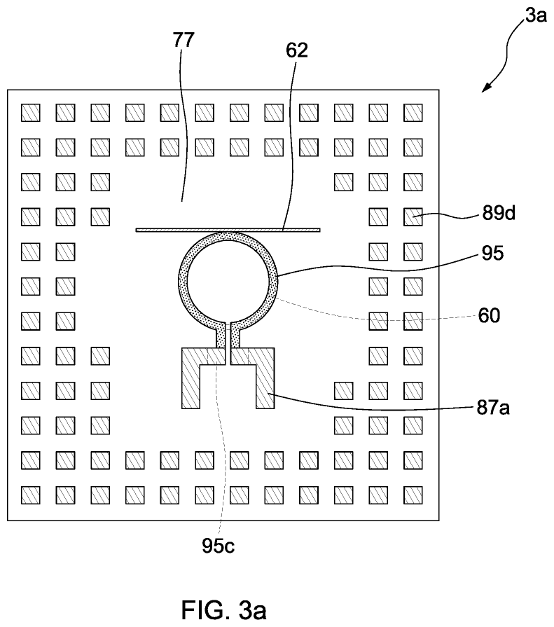

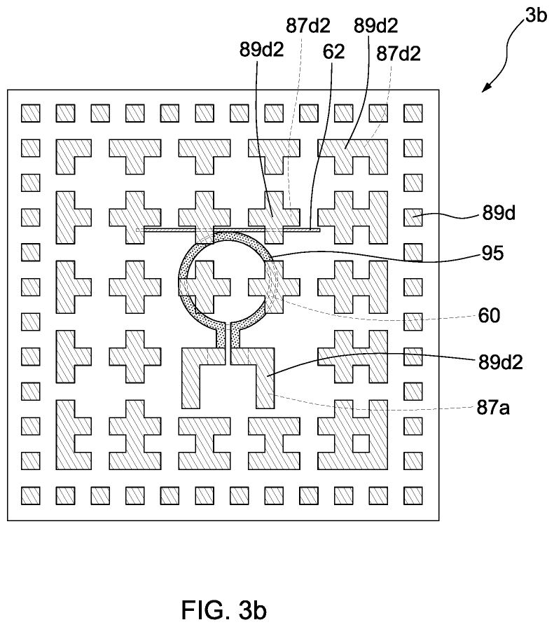

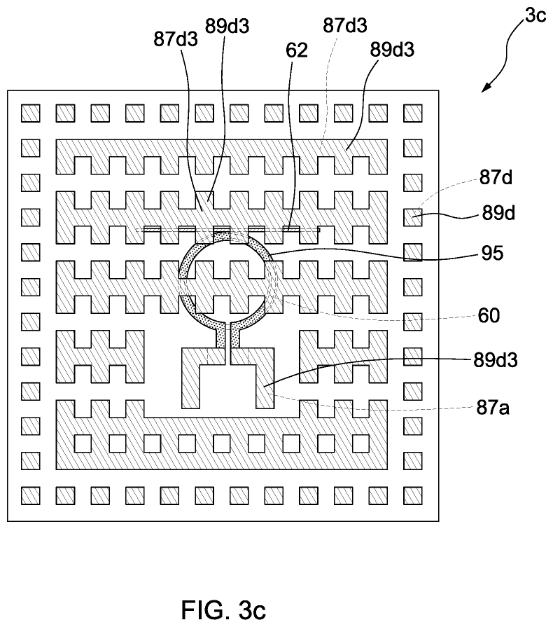

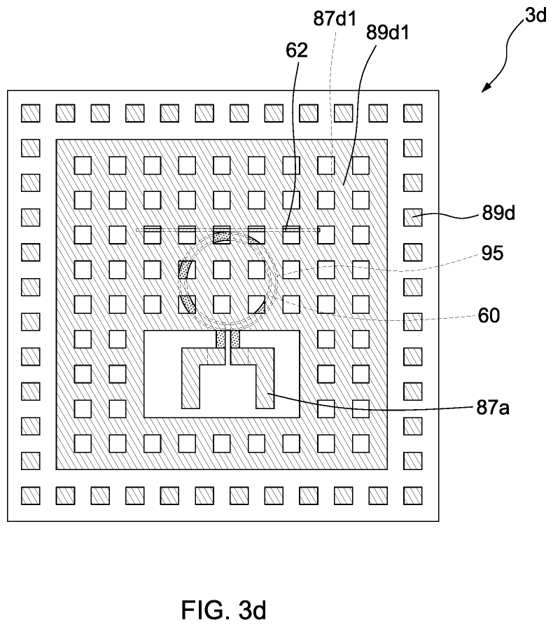

FIG. 3a is a diagram of a semiconductor device 3a from a top view in accordance with some embodiments of the present disclosure. The semiconductor device 3a includes a semiconductor substrate 10, a first dielectric layer 20, dielectric layers 23 and 24, a second dielectric layer 22, an annular waveguide 60, a strip waveguide 62, a heater 95, first dummy interconnects 87d (not show), first conductive interconnects 87a, and second dummy interconnects 89d. The heater 95 is annular from a top view. The second conductive layer 89 includes a clearance zone 77 above the heater 95 from the top view. No second dummy interconnect 89d is disposed in the clearance zone 77 from the top view. In some embodiments, no dummy interconnect 87d is disposed in the clearance zone 77 from the top view.

FIG. 3b is a diagram of a semiconductor device 3b from a top view in accordance with some embodiments of the present disclosure. An area of a vertical projection of one of the second dummy interconnects 89d2 is equal to an area of a vertical projection of one of the first dummy interconnects 87d2. A vertical projection of one of the second dummy interconnects 89d2 is aligned with a vertical projection of a corresponding first dummy interconnect 87d2. That is, some of the second dummy interconnects 89d2 overlap corresponding first dummy interconnects 87d2 from the top view, and thus in FIG. 3b, two of the first dummy interconnects 87d2 are annotated with a dotted line, while two of the second dummy interconnects 89d2 are annotated with a solid line.

A first conductive layer 87 comprising a plurality of first conductive interconnects 87a is disposed above and electrically connected to the annular heater 95. A portion 87d2 of the first conductive layer 87 is disposed directly above one portion of the annular heater 95 and the portion 87d2 of the first conductive layer 87 is not disposed directly above the other portion of the annular heater 95. In some embodiments, no dummy interconnect 89d2 is directly disposed above the other portion of the annular heater 95 from the top view. No dummy interconnect 89d is directly disposed above the annular heater 95 from the top view.

A second conductive layer 89 comprises a plurality of second dummy interconnects 89d disposed above the first conductive layer 87 and a plurality of dummy interconnects 89d2 disposed above the annular heater 95. A vertical projection of one of the plurality of second dummy interconnects 89d2 falls on a vertical projection of one of the plurality of first conductive interconnects 87a. A vertical projection of the conductive layer 89 falls on a vertical projection of one portion of the annular heater 95. A vertical projection of the conductive layer 89 falls on one portion of the annular heater 95.

FIG. 3c is a diagram of a semiconductor device 3c from a top view in accordance with some embodiments of the present disclosure. An area of a vertical projection of one of the dummy interconnects 89d3 is equal to an area of a vertical projection of one of the dummy interconnects 87d3. A vertical projection of one of the second dummy interconnects 89d3 is aligned with a vertical projection of a corresponding one of the first dummy interconnects 87d3 from a top view.

A first conductive layer 87 comprising a plurality of dummy interconnects 87d and a plurality of first conductive interconnects 87a disposed above and electrically connected to the annular heater 95. A vertical projection of one of the second dummy interconnects 89d is aligned with a vertical projection of a corresponding one of the first dummy interconnects 87d from a top view. A portion of dummy interconnects 87d3 of the first conductive layer 87 is disposed directly above one portion of the annular heater 95 and the portion 87d3 of the first conductive layer 87 is not disposed directly above the other portion of the annular heater 95. In some embodiments, no dummy interconnect 89d3 is directly disposed above the other portion of the annular heater 95 from the top view. No dummy interconnect 89d is directly disposed above the annular heater 95 from the top view. One portion of dummy interconnects 89d3 is disposed directly above one portion of the strip waveguide 62 and the other portion of dummy interconnects 89d3 is not disposed directly above one portion of the strip waveguide 62.

A second conductive layer 89 comprises a plurality of second dummy interconnects 89d3 disposed above the first conductive layer 87 and a plurality of dummy interconnects 89d3 disposed above the annular heater 95. A vertical projection of one of the plurality of second dummy interconnects 89d3 falls on a vertical projection of one of the plurality of first conductive interconnects 87a. A vertical projection of the conductive layer 89 falls on a vertical projection of one portion of the annular heater 95. A vertical projection of the conductive layer 89 falls on one portion of the annular heater 95. A vertical projection of the conductive layer 89 does not fall on the other portion of the annular heater 95.

FIG. 3d is a diagram of a semiconductor device 3d from a top view in accordance with some embodiments of the present disclosure. An area of a vertical projection of one of the dummy interconnects 89d1 is equal to an area of a vertical projection of one of the dummy interconnects 87d1. A vertical projection of one of the second dummy interconnects 89d1 is aligned with a vertical projection of a corresponding one of the first dummy interconnects 87d1 from a top view. A portion of dummy interconnects 87d1 of the first conductive layer 87 is disposed directly above one portion of the annular heater 95 and the waveguide, and a portion of dummy interconnects 87d1 of the first conductive layer 87 is not disposed directly above the other portion of the annular heater 95 and the waveguide 62.

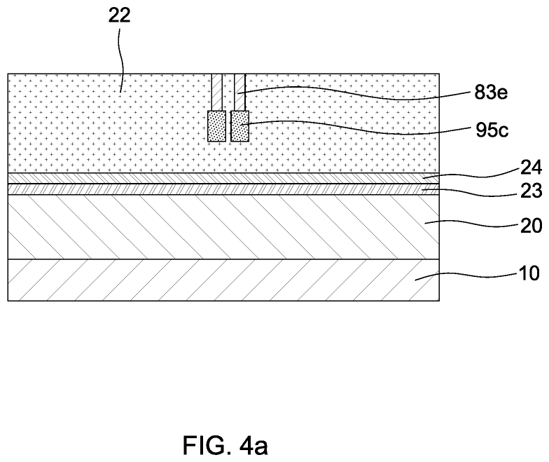

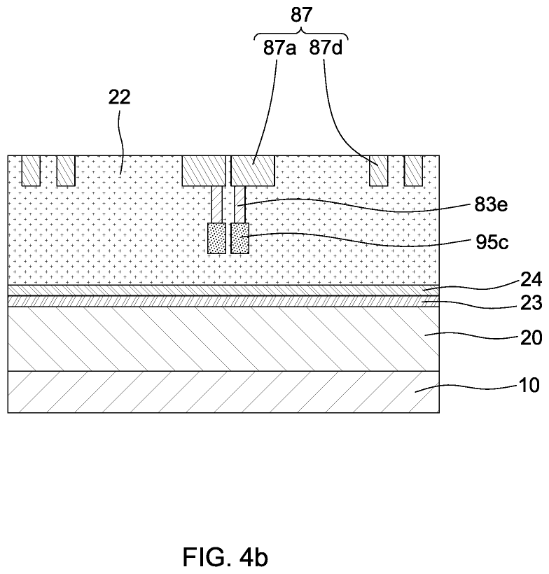

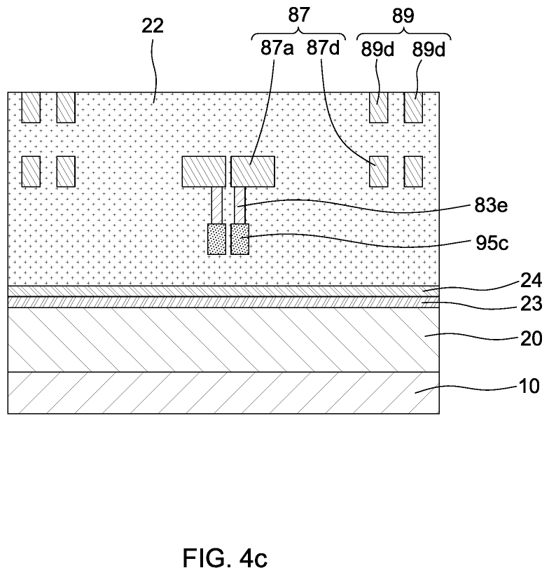

FIGS. 4a, 4b, and 4c illustrate a method for manufacturing the semiconductor device shown in FIG. 1, in accordance with some embodiments of the present disclosure. Referring to FIG. 4a, a semiconductor substrate 10 is provided. In some embodiments, the semiconductor substrate 10 includes materials such as silicon, GaAs, germanium, SOI or other suitable semiconductive materials. A dielectric layer 20 is formed or provided on the top surface of the semiconductor substrate 10. The dielectric layer 20 can be formed with various processes, such as CVD or spin-coating. The dielectric layer 20 includes dielectric materials such as SiO₂, SiN, SiCOH, a spin-on low-k dielectric material such as SiLK™, etc, or other suitable materials. In some embodiments, the thickness of the dielectric layer 20 ranges from approximately 1.5 μm to 2 μm. The waveguide 60 (not shown) is disposed in the first dielectric layer 20. A third dielectric layer 23 is disposed on the top surface of the first dielectric layer 20. In some embodiments, the third dielectric layer 23 includes dielectric materials such as SiO₂, SiN, SiCOH, a spin-on low-k dielectric material, etc, or other suitable materials. In some embodiments, the third dielectric layer 23 includes SiO₂. A fourth dielectric layer 24 is formed on the third dielectric layer 23. The fourth dielectric layer 24 covers the third dielectric layer 23. In some embodiments, the fourth dielectric layer 24 includes dielectric materials such as SiN, or other suitable materials. The second dielectric layer 22 is disposed on the fourth dielectric layer 24. The second dielectric layer 22 includes dielectric materials such as SiO₂, SiN, SiCOH, a spin-on low-k dielectric material such as SiLK™, etc, or other suitable materials. In some embodiments, the second dielectric layer 22 includes SiO₂. A heater 95 (not shown) is formed in the second dielectric layer 22. The conductive pad 95c of the heater 95 is formed in the second dielectric layer 22. In some embodiments, the conductive pad 95c includes material such as copper (Cu) or other suitable metals. The thickness of the heater 95 ranges from approximately 1500 A to 3000 A. A distance between a bottom surface of the heater 95 and a top surface of the fourth dielectric layer 24 ranges from approximately 3000 Å to 12000 Å.

Referring to FIG. 4b, conductive contacts 83e are formed in the dielectric layer 22 and above the heater 95. A plurality of first conductive interconnects 87a and dummy interconnects 87d are formed above the heater 95. The conductive contacts 83e are electrically connected to one of the plurality of first conductive interconnects 87a and to the heater 95. The conductive contacts 83e can include material identical to that of the heater 95. The plurality of first conductive interconnects 87a and dummy interconnects 87d can include material different from that of the heater 95. In some embodiments, the plurality of first conductive interconnects 87a and dummy interconnects 87d include material such as copper (Cu) or other suitable metals.

Referring to FIG. 4c, the thickness of the dielectric layer 22 can be increased by deposition. The second conductive layer 89 including a plurality of second dummy interconnects 89d is formed in the dielectric layer 22. In some embodiments, the second conductive layer 89 and the plurality of second dummy interconnects 89d include material such as copper (Cu) or other suitable metals. After the second conductive layer 89 is formed, the semiconductor device 1 shown in FIG. 1a is obtained. FIG. 4c illustrates the semiconductor device 1 along line 1b-1b′ of FIG. 1a.

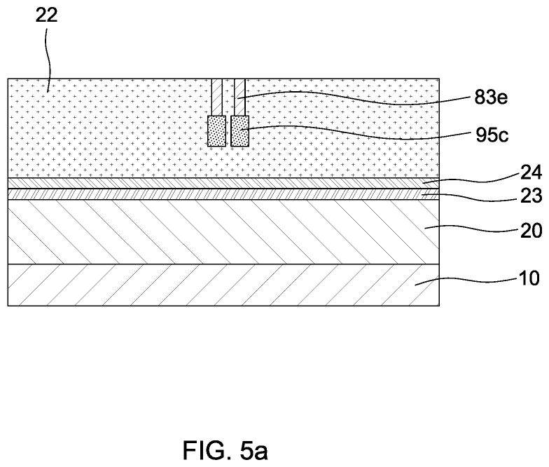

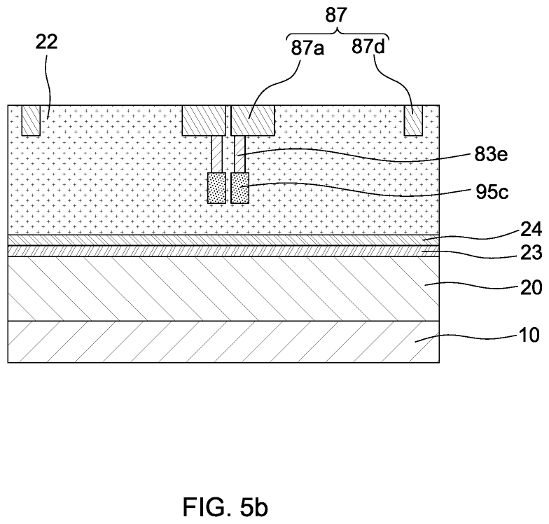

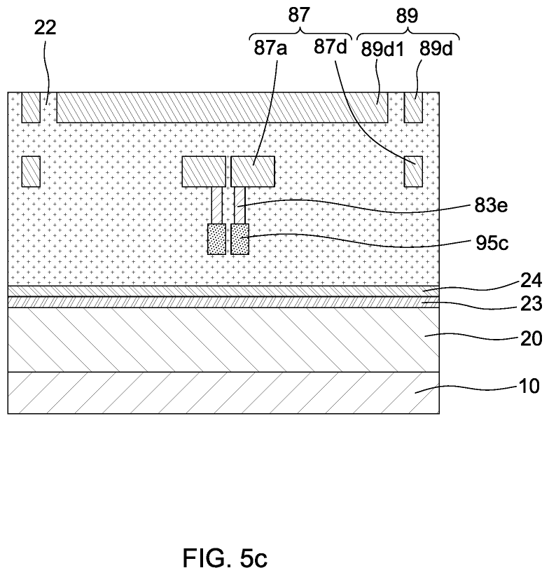

FIGS. 5a, 5b, and 5c illustrate a method for manufacturing the semiconductor device shown in FIG. 2a, in accordance with some embodiments of the present disclosure. Referring to FIG. 5a, a semiconductor substrate 10 is provided. In some embodiments, the semiconductor substrate 10 includes materials such as silicon, GaAs, germanium, SOI or other suitable semiconductive materials. A dielectric layer 20 is formed or provided on the top surface of the semiconductor substrate 10. The dielectric layer 20 can be formed in various processes, such as CVD or spin-coating. The dielectric layer 20 includes dielectric materials such as SiO₂, SiN, SiCOH, a spin-on low-k dielectric material such as SiLK™, etc, or other suitable materials. In some embodiments, the thickness of the dielectric layer 20 ranges from approximately 1.5 μm to 2 μm. The waveguide 60 (not shown) is disposed in the first dielectric layer 20. A third dielectric layer 23 is disposed on the top surface of the first dielectric layer 20. In some embodiments, the third dielectric layer 23 includes dielectric materials such as SiO₂, SiN, SiCOH, a spin-on low-k dielectric material, etc, or other suitable materials. In some embodiments, the third dielectric layer 23 includes SiO₂. A fourth dielectric layer 24 is formed on the third dielectric layer 23. The fourth dielectric layer 24 covers the third dielectric layer 23. In some embodiments, the fourth dielectric layer 24 includes dielectric materials such as SiN, or other suitable materials. The second dielectric layer 22 is disposed on the fourth dielectric layer 24. The second dielectric layer 22 includes dielectric materials such as SiO₂, SiN, SiCOH, a spin-on low-k dielectric material such as SiLK™, etc, or other suitable materials. In some embodiments, the second dielectric layer 22 includes SiO₂. A heater 95 (not shown) is formed in the second dielectric layer 22. The conductive pad 95c of the heater 95 is formed in the second dielectric layer 22. The thickness of the heater 95 ranges from approximately 1500 A to 3000 A. A distance between a bottom surface of the heater 95 and a top surface of the fourth dielectric layer 24 ranges from approximately 3000 Å to 12000 Å.

Referring to FIG. 5b, conductive contacts 83e are formed in the dielectric layer 22 and above the heater 95. A plurality of first conductive interconnects 87a and dummy interconnects 87d are formed above the heater 95. The conductive contacts 83e are electrically connected to one of the plurality of first conductive interconnects 87a and to the heater 95. The conductive contacts 83e can include material identical to that of the heater 95. The plurality of first conductive interconnects 87a and dummy interconnects 87d can include material different from that of the heater 95. In some embodiments, the plurality of first conductive interconnects 87a and dummy interconnects 87d include material such as copper (Cu) or other suitable metals.

Referring to FIG. 5c, the thickness of the dielectric layer 22 can be increased by deposition. The second conductive layer 89 including a plurality of second dummy interconnects 89d and dummy interconnects 89d1 is formed in the dielectric layer 22. In some embodiments, the second conductive layer 89, the plurality of second dummy interconnects 89d and dummy interconnects 89d1 include material such as copper (Cu) or other suitable metals. After the second conductive layer 89 is formed, the semiconductor device 2 shown in FIG. 2a is obtained. FIG. 5c illustrates the semiconductor device 2 along line 2b-2b′ of FIG. 2a.

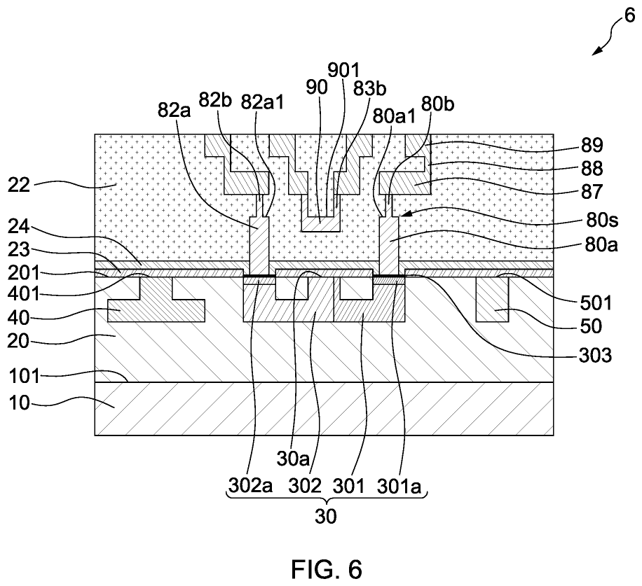

FIG. 6 is a diagram of a semiconductor device 6 in accordance with some embodiments of the present disclosure. FIG. 6 shows a semiconductor device 6. The semiconductor device 6 includes a semiconductor substrate 10, a first dielectric layer 20, a second dielectric layer 22, a light modulator 30, a first waveguide 50, a second waveguide 40, a heater 90, first conductive contacts 80a and 82a, and second conductive contacts 80b and 82b. In some embodiments, the light modulator 30 can be an annular waveguide. In some embodiments, the first waveguide 50 and the second waveguide 40 can each be a strip waveguide.

In the semiconductor substrate 10 as shown, some features have been omitted for simplification. For example, the semiconductor substrate 10 may include CMOS transistors or other electric components such as resistors, diodes etc. In some embodiments, the semiconductor substrate 10 includes several materials such as silicon, GaAs, germanium, silicon on insulator (SOI) or other suitable semiconductive materials.

The first dielectric layer 20 can be formed by various processes, such as chemical vapor deposition (CVD) or spin-coating. The first dielectric layer 20 covers the semiconductor substrate 10 and provides electrical insulation between the semiconductor substrate 10 and overlaid conductive features. The first dielectric layer 20 is disposed on the semiconductor substrate 10. The first dielectric layer 20 covers a top surface 101 of the semiconductor substrate 10. The first dielectric layer 20 includes dielectric materials such as silicon oxide (SiO₂), silicon nitride (SiN), SiCOH, a spin-on low-k dielectric material such as SiLK™, etc, or other suitable materials. In some embodiments, the thickness of the first dielectric layer 20 ranges from approximately 1.5 micrometers (μm) to 2 μm.

The light modulator 30 is disposed in the first dielectric layer 20. The light modulator 30 is embedded within the first dielectric layer 20. The thickness of the light modulator 30 (i.e., the distance between the top surface and the bottom surface of the light modulator 30) ranges from approximately 200 nm to 240 nm. The thickness of the first waveguide 50 and second waveguide 40 ranges from approximately 200 nm to 240 nm. Integrating a PN junction into a waveguide structure (such as the light modulator 30) enables a building block of a photonic integrated circuit of a phase modulator. The light modulator 30 is configured to modulate a frequency of light passing through the first waveguide 50. The light modulator 30 is configured to modulate a frequency of light passing through the second waveguide 40. The PN junction of the light modulator 30 is configured to modulate or adjust the photonics passing through the first waveguide 50 and the second waveguide 40.

The light modulator 30 includes a n-type doped region 301, a p-type doped region 302, a n-plus doped layer 301a disposed on the n-type doped region 301, and a p-plus doped layer 302a disposed on the p-type doped region 302. The n-plus doped layer 301a includes N type impurity dopant of high concentration and the p-plus doped layer 302a includes P type impurity dopant of high concentration. In some embodiments, the region 301 may be a n-minus doped region and the region 302 may be a p-minus doped region. A conductive silicide layer 303 is disposed on the p-plus doped layer 302a and the n-plus doped layer 301a. In some embodiments, the conductive silicide layer 303 includes cobalt-silicide (Co silicide), nickel-silicide (Ni silicide), or other suitable materials.

The first conductive contacts 80a and 82a are disposed on the conductive silicide layer 303. The first conductive contact 80a is electrically connected to the conductive silicide layer 303 and the conductive silicide layer 303 is electrically connected to the n-plus doped layer 301a. The first conductive contacts 80a and 82a include tungsten or other suitable material. If the first conductive contact 80a (e.g., including the tungsten) directly contacts the n-plus doped layer 301a, resistance will be high. If the first conductive contact 80a contacts the conductive silicide layer 303 and the conductive silicide layer 303 contacts the n-plus doped layer 301a, the resistance will be low.

The first waveguide 50 is embedded within the first dielectric layer 20. A top surface 201 of the first dielectric layer 20 is coplanar with a top surface 501 of the first waveguide 50 and a top surface 30a of the light modulator 30. The second waveguide 40 is embedded within the first dielectric layer 20. A top surface 401 of the second waveguide 40 is coplanar with the top surface 201 of the first dielectric layer 20 and the top surface 501 of the first waveguide 50. In some embodiments, the first waveguide 50 includes a strip waveguide and the second waveguide 40 includes a rib waveguide. In some embodiments, the top surface 501, the top surface 30a, and the top surface 401 are coplanar with the top surface 201. In some embodiments, the first waveguide 50, second waveguide 40 and light modulator 30 can be formed by shallow Si etching and deep Si etching of the first dielectric layer 20.

A third dielectric layer 23 is disposed between the first dielectric layer 20 and the second dielectric layer 22. A level of a top surface of the conductive silicide layer 303 is lower than a level of a top surface of the third dielectric layer 23. In some embodiments, an elevation level of the top surface of the conductive silicide layer 303 is lower than an elevation level of the top surface of the third dielectric layer 23. In some embodiments, the third dielectric layer 23 includes dielectric materials such as SiO₂, SiN, SiCOH, a spin-on low-k dielectric material, or other suitable materials. A fourth dielectric layer 24 is disposed on the third dielectric layer 23. The fourth dielectric layer 24 surrounds a portion of a side surface of the first conductive contacts 80a and 82a. The fourth dielectric layer 24 is disposed between the third dielectric layer 23 and the second dielectric layer 22. A portion of the fourth dielectric layer 24 is recessed from the top surface of the third dielectric layer 23 and is disposed in the third dielectric layer 23. In some embodiments, the fourth dielectric layer 24 includes dielectric materials such as SiN, or other suitable materials.

The second dielectric layer 22 is disposed on the first dielectric layer 20. In some embodiments, the second dielectric layer 22 includes the same material as the first dielectric layer 20. The heater 90 is disposed in the second dielectric layer 22 and disposed above the light modulator 30. In some embodiments, the heater 90 includes tungsten (W). In some embodiments, the heater 90 can include nichrome, FeCrAl, Cupronickel (CuNi), or any other suitable materials.

The first conductive contacts 80a and 82a include material identical to that of the heater 90. The heater 90 is configured to control the photons transmitted in the light modulator 30 by increasing the temperature of the light modulator 30. The heater 90 is configured to adjust the frequency of the light passing through the light modulator 30 by increasing the temperature of the light modulator 30. The heater 90 is usually utilized in silicon photonics in use of the thermo-optic effects of Si to manipulate the photons within the waveguide (e.g., the function of the heater 90 would stabilize a micro-ring resonator and be used as a switch to control the modulator 30, . . . , etc.). A distance between a bottom surface of the heater 90 and a top surface of the fourth dielectric layer 24 ranges from approximately 3000 Å to 12000 Å. The thickness of the heater 90 ranges from approximately 1500 Å to 3000 Å. The perpendicular length of the first conductive contacts 80a and 82a ranges from approximately 3000 Å to 15000 Å.

The first conductive contacts 80a and 82a are electrically connected to the light modulator 30. A top surface 901 of the heater 90 is coplanar with a top surface 80al of the first conductive contact 80a and a top surface 82al of the first conductive contact 82a. The second conductive contacts 80b and 82b are disposed on the first conductive contacts 80a and 82a. The second conductive contacts 80b and 82b include a material of tungsten or other suitable material. The second conductive contact 80b extends perpendicular to the top surface 80al of the first conductive contact 80a. The second conductive contact 82b extends perpendicular to the top surface 82al of the first conductive contact 82a. The first conductive contact 80a and the second conductive contact 80b define a stepped structure 80s. In some embodiments, a projection area of the second conductive contact 80b is smaller than the area of a top surface 80al of the first conductive contact 80a. In some embodiments, a projection area of the first conductive contacts 80a and 82a is respectively smaller than the area of a top surface of the n-plus doped layer 301a or a top surface of the p-plus doped layer 302a. In some embodiments, the stepped structure 80s is located at the interface between the first conductive contact 80a and the second conductive contact 80b. The stepped structure 80s is formed due to the lateral width of the second conductive contact 80b being less than that of the first conductive contact 80a. In some embodiments, the first conductive contact 80a and the second conductive contact 80b includes tungsten identical to that of the heater 90. The perpendicular length of the second conductive contacts 80b and 82b ranges from approximately 2000 Å to 6000 Å.

Conductive interconnects 87, 88, and 89 are formed on the second conductive contacts 80b and 82b and third conductive contacts 83b. The lateral width of the conductive interconnect 88 is less than that of the conductive interconnects 87 and 89. The lateral width of the conductive interconnect 89 is less than that of the conductive interconnect 87. In some embodiments, the conductive interconnects 87, 88, and 89 include material different from that of the heater 90. In some embodiments, the conductive interconnects 87, 88, and 89 include material different from that of the second conductive contacts 80b and 82b. In some embodiments, the conductive interconnects 87, 88, and 89 include material different from that of the third conductive contacts 83b. In some embodiments, the conductive interconnects 87, 88, and 89 include material such as copper (Cu) or other suitable metals. The lateral width of the second conductive contacts 80b and 82b is less than that of the conductive interconnect 87. The perpendicular length of the conductive interconnects 87, 88, and 89 ranges from approximately 0.5 μm to 5.5 μm.

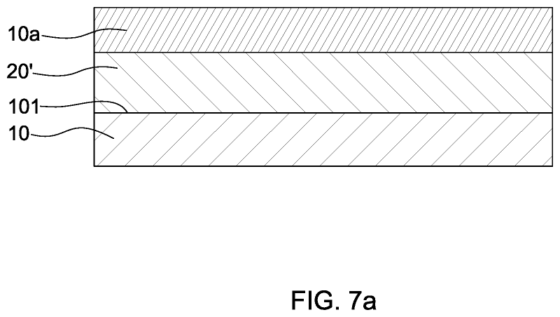

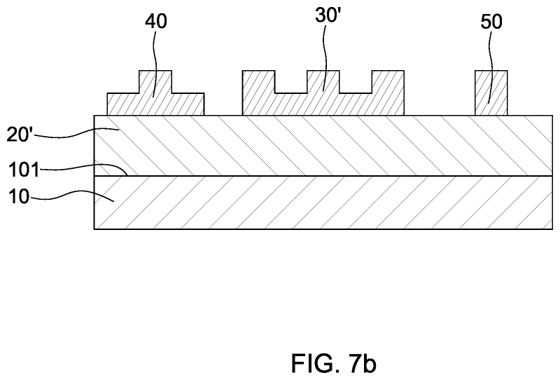

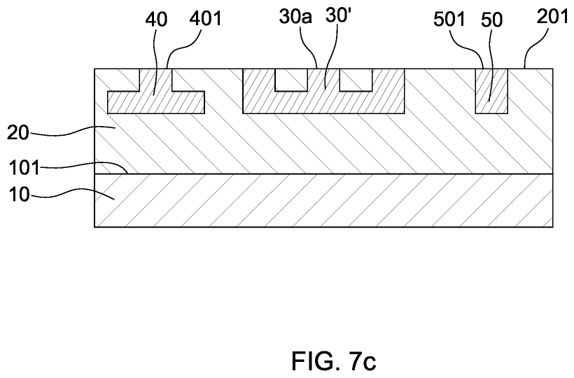

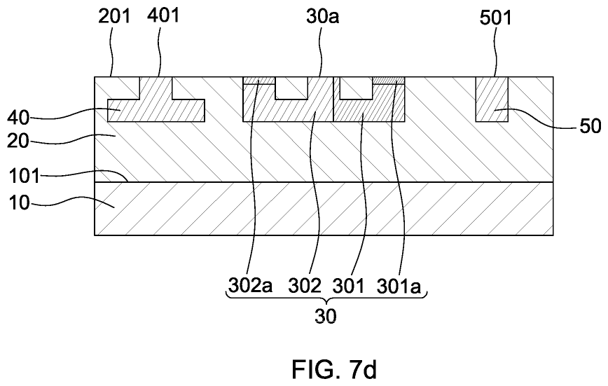

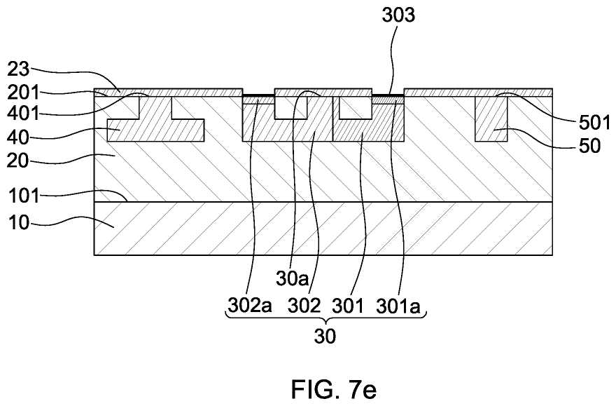

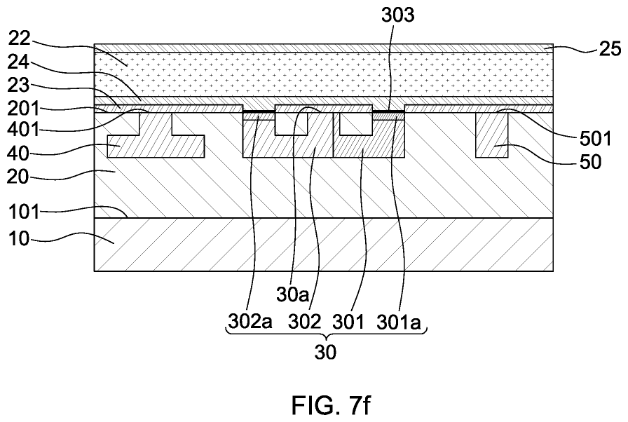

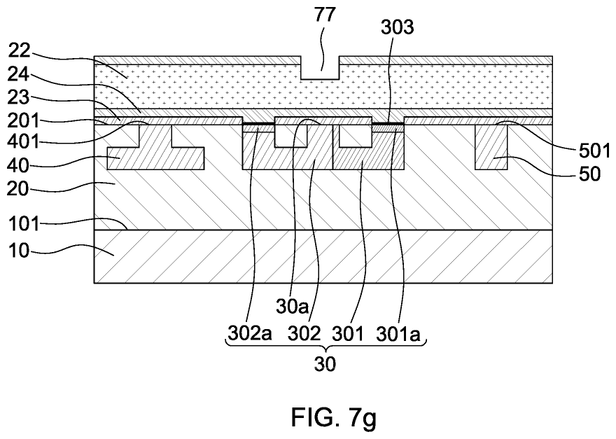

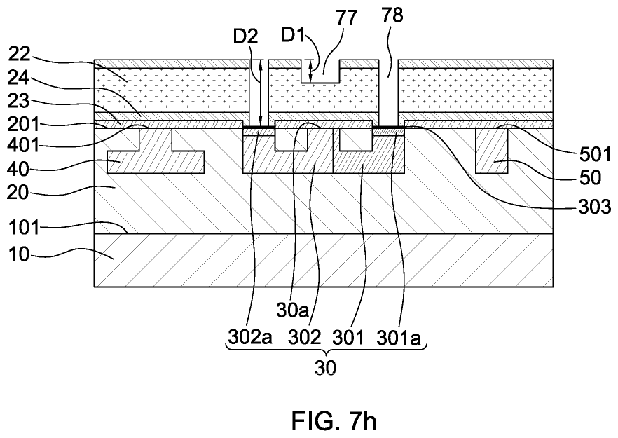

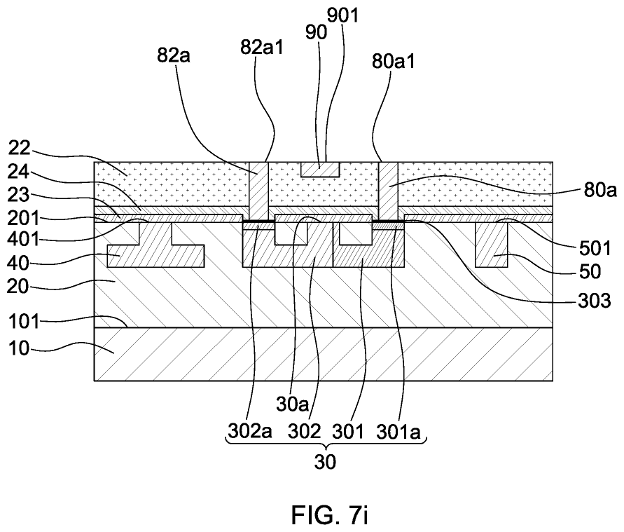

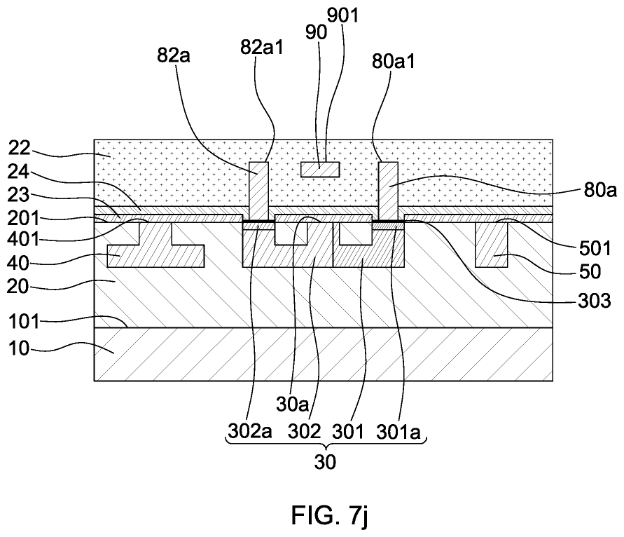

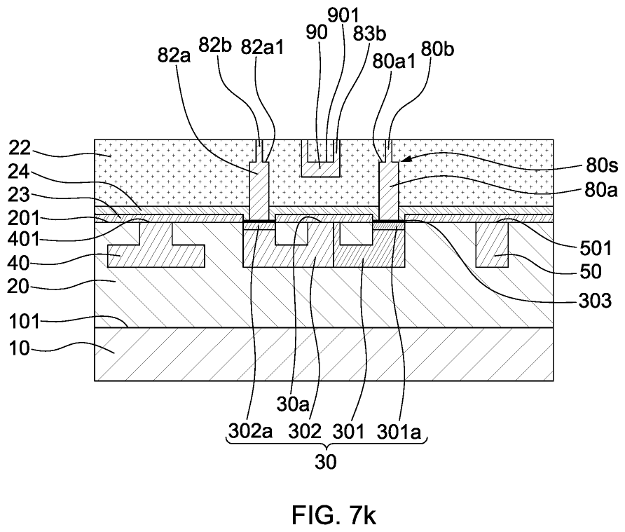

FIGS. 7a, 7b, 7c, 7d, 7e, 7f, 7g, 7h, 7i, 7j, and 7k illustrate a method for manufacturing the semiconductor device 6 shown in FIG. 6, in accordance with some embodiments of the present disclosure. Referring to FIG. 7a, a semiconductor substrate 10 is provided. The semiconductor substrate 10 includes a top surface 101. In some embodiments, the semiconductor substrate 10 includes several materials such as silicon, GaAs, germanium, SOI or other suitable semiconductive materials. A dielectric layer 20′ is formed or provided on the top surface 101 of the semiconductor substrate 10. The dielectric layer 20′ can be formed with various processes, such as CVD or spin-coating. The dielectric layer 20′ includes dielectric materials such as SiO₂, SiN, SiCOH, a spin-on low-k dielectric material such as SiLK™, etc, or other suitable materials. In some embodiments, the thickness of the dielectric layer 20′ ranges from approximately 1.5 μm to 2 μm. A silicon layer 10a is formed or provided on dielectric layer 20′. In some embodiments, the thickness of the silicon layer 10a ranges from approximately 200 nm to 240 nm.

Referring to FIG. 7b, a first waveguide 50, a second waveguide 40, and a silicon structure 30′ are formed by shallow Si etching and/or deep Si etching of the silicon layer 10a. In some embodiments, the first waveguide 50 is formed by deep Si etching of the silicon layer 10a. In some embodiments, the second waveguide 40 and the silicon structure 30′ are formed by shallow Si etching of the silicon layer 10a.

Referring to FIG. 7c, a material the same as the dielectric layer 20′ is disposed to cover the first waveguide 50, second waveguide 40, and silicon structure 30′, and then a dielectric layer 20 is formed. The top surface 201 of the dielectric layer 20 is coplanar with the top surface 501 of the first waveguide 50, the top surface 30a of the silicon structure 30′, and the top surface 401 of the second waveguide 40.

Referring to FIG. 7d, a N type impurity dopant of relatively low concentration is implanted in a n-type doped region 301 and a P type impurity dopant of relatively low concentration is implanted in a p-type doped region 302. In some embodiments, the region 301 may be a n-minus doped region and the region 302 may be a p-minus doped region. A N type impurity dopant of relatively high concentration is implanted in a n-plus doped layer 301a and a P type impurity dopant of relatively high concentration is implanted in a p-plus doped layer 302a. The light modulator 30 is formed after the impurity dopants are implanted. The light modulator 30 includes a n-type doped region 301, a p-type doped region 302, a n-plus doped layer 301a, and a p-plus doped layer 302a.

Referring to FIG. 7e, a third dielectric layer 23 is disposed on the first top surface 201 of the first dielectric layer 20. The top surface of the p-plus doped layer 302a and the top surface of the n-plus doped layer 301a are exposed by the third dielectric layer 23. A conductive silicide layer 303 is formed on the top surface of the p-plus doped layer 302a and the top surface of the n-plus doped layer 301a. In some embodiments, the third dielectric layer 23 includes dielectric materials such as SiO₂, SiN, SiCOH, a spin-on low-k dielectric material, etc, or other suitable materials. In some embodiments, the third dielectric layer 23 includes SiO₂. A top surface of the conductive silicide layer 303 is exposed by the third dielectric layer 23. The level of the top surface of the conductive silicide layer 303 is lower than a top surface of the third dielectric layer 23.

Referring to FIG. 7f, a fourth dielectric layer 24 is formed on the third dielectric layer 23. The fourth dielectric layer 24 covers the third dielectric layer 23 and the conductive silicide layer 303. A portion of the fourth dielectric layer 24 is recessed from the top surface of the third dielectric layer 23 and is surrounded by the third dielectric layer 23. In some embodiments, the fourth dielectric layer 24 includes dielectric materials such as SiN, or other suitable materials. The second dielectric layer 22 is disposed on the fourth dielectric layer 24. The second dielectric layer 22 includes dielectric materials such as SiO₂, SiN, SiCOH, a spin-on low-k dielectric material such as SiLK™, etc, or other suitable materials. In some embodiments, the second dielectric layer 22 includes SiO₂. A fifth dielectric layer 25 is formed on the second dielectric layer 22. In some embodiments, the fifth dielectric layer 25 includes dielectric materials such as silicon oxynitride (SiON).

Referring to FIG. 7g, a recess 77 is formed, for example, by etching the second dielectric layer 22 and fifth dielectric layer 25. The recess 77 passes through the fifth dielectric layer 25 and a portion of the second dielectric layer 22.

Referring to FIG. 7h, two additional recesses 78 are formed, for example, by etching the second dielectric layer 22, fifth dielectric layer 25, fourth dielectric layer 24, and third dielectric layer 23. After etching, the top surface of the conductive silicide layer 303 is exposed. A first depth D1 of the first recess 77 is different from the second depth D2 of the second recess 78. The second depth D2 is larger than the first depth D1.

Referring to FIG. 7i, the recess 77 and recesses 78 are filled in the same operation with a conductive material. The conductive material filled within the recess 77 and recesses 78 can include tungsten (W), nichrome, FeCrAl, Cupronickel (CuNi), or any other suitable materials. The filling of recess 77 and recesses 78 can be performed at the same time. After filling, a heater 90 is formed within the recess 77, and first conductive contacts 80a and 82a are formed within the recesses 78. A top surface 80al of the first conductive contacts 80a and a top surface 82al of the first conductive contacts 82a are coplanar with a top surface 901 of the heater 90. The thickness of the heater 90 ranges from approximately 1500 A to 3000 A. A distance between a bottom surface of the heater 90 and a top surface of the fourth dielectric layer 24 ranges from approximately 3000 Å to 12000 Å.

Referring to FIG. 7j, a material the same as the second dielectric layer 22 is formed on the second dielectric layer 20 to cover the first conductive contacts 80a and 82a and the heater 90.

Referring to FIG. 7k, second conductive contacts 80b and 82b are formed on the first conductive contacts 80a and 82a. Third conductive contacts 83b are formed on the heater 90. The third conductive contacts 83b can include material identical to that of the heater 90. The third conductive contacts 83b include tungsten or other suitable material. The third conductive contacts 83b are in contact with the heater 90. The operation for filling the second conductive contacts 80b and 82b uses the same material, such as tungsten. The second conductive contacts 80b and 82b can include material identical to that of the third conductive contacts 83b. The second conductive contacts 80b and 82b, and the third conductive contacts 83b can include material identical to that of the heater 90.

When formation of the first conductive contacts 80a and 82a, the heater 90 and second conductive contacts 80b and 82b uses the same material, formation can be performed by the same machine. That is, it is unnecessary to change machines during formation of a heater and first and second conductive contacts. The formation of the heater 90, first conductive contacts 80a and 82a, and second conductive contacts 80b and 82b can be performed by the same machine. Therefore, in order to form a heater and conductive contacts, contamination (such as forming a heater by using Titanium nitride (TiN)) between machines can be avoided. The etching for TiN was performed before formation of the contacts. Etching is incompatible with the operation for forming tungsten, because a dedicated etching machine is needed for etching TiN and the changing of the dedicated etching machine is thus not economical.

The second conductive contacts 80b and 82b extend perpendicular to the top surface 80al of the first conductive contacts 80a and 82a. In some embodiments, the first conductive contact 80a and the second conductive contact 80b define a stepped structure 80s due to a projection area of the second conductive contact 80b being smaller than the area of a top surface 80al of the first conductive contact 80a. A side surface of the second conductive contact 80b is not coplanar with a side surface of the first conductive contact 80a. The perpendicular length of the first conductive contacts 80a and 82a ranges from approximately 3000 Å to 15000 Å. The perpendicular length of the second conductive contacts 80b and 82b ranges from approximately 2000 Å to 6000 Å.

Material the same as the second dielectric layer 22 is formed on the second dielectric layer 22 to cover the second conductive contacts 80b and 82b and third conductive contacts 83b. Next, conductive interconnects 87, 88, and 89 are formed in the second dielectric layer 22 by multiple etching and filling operations. The conductive interconnects 87, 88, and 89 include several materials such as Cu or other suitable materials. After the conductive interconnects 87, 88, and 89 are formed, the semiconductor device 6 shown in FIG. 6 is obtained.

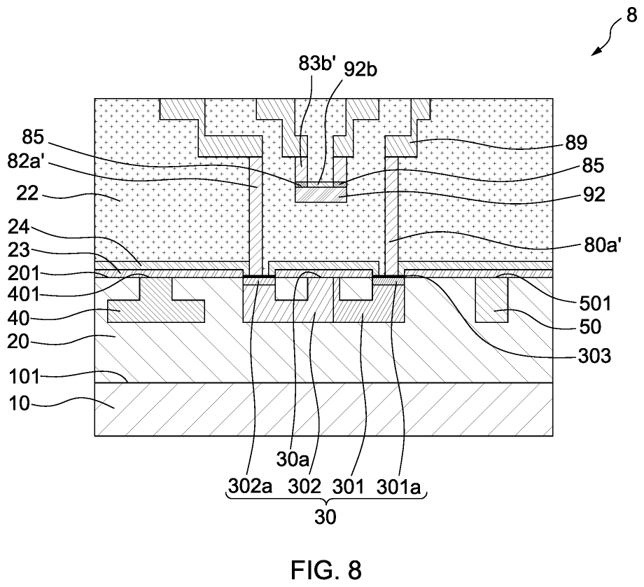

FIG. 8 is a diagram of a semiconductor device 8 in accordance with some embodiments of the present disclosure. FIG. 8 shows a semiconductor device 8. The semiconductor device 8 is similar to the semiconductor device 6 shown in FIG. 6 except the heater 92 and the conductive contacts 80a′, 82a′, and 83a′. The semiconductor device 8 includes a semiconductor substrate 10, a first dielectric layer 20, a second dielectric layer 22, a light modulator 30, a first waveguide 50, a second waveguide 40, a heater 92, first conductive contacts 80a′ and 82a′, and third conductive contacts 83a′.

In some embodiments, the semiconductor substrate 10 includes materials such as silicon, GaAs, germanium, SOI, or other suitable semiconductive materials. The first dielectric layer 20 is disposed on the semiconductor substrate 10. The first dielectric layer 20 includes dielectric materials such as SiO₂, SiN, SiCOH, a spin-on low-k dielectric material such as SiLK™, etc, or other suitable materials. The light modulator 30 is disposed in the first dielectric layer 20. The thickness of the light modulator 30 ranges from approximately 200 nm to 240 nm. The thickness of the first waveguide 50 and second waveguide 40 ranges from approximately 200 nm to 240 nm. The light modulator 30 is configured to modulate a frequency of light passing through the first waveguide 50 and the second waveguide 40.

The light modulator 30 includes a n-type doped region 301, a p-type doped region 302, a n-plus doped layer 301a disposed on the n-type doped region 301, and a p-plus doped layer 302a disposed on the p-type doped region 302. A conductive silicide layer 303 is disposed on the p-plus doped layer 302a and the n-plus doped layer 301a. In some embodiments, the conductive silicide layer 303 includes Co silicide or Ni silicide, or other suitable materials. The first conductive contact 80a′ is electrically connected to the conductive silicide layer 303 and the conductive silicide layer 303 is electrically connected to the n-plus doped layer 301a. The first conductive contact 82a′ is electrically connected to the conductive silicide layer 303 and the conductive silicide layer 303 is electrically connected to the p-plus doped layer 302a.

The third conductive contacts 80a′ and 82a′ include tungsten. In some embodiments, the third conductive contacts 83b′ include tungsten. The heater 92 includes a material different from that of the third conductive contacts 80a′ and 82a′. In some embodiments, the heater 92 includes Titanium nitride (TiN). In some embodiments, a seed layer 85 is formed on the heater 92. The seed layer 85 is electrically connected to the heater 92. In some embodiments, the seed layer 85 includes Titanium (Ti). The third conductive contacts 83b′ is electrically connected to the seed layer 85. A distance between a bottom surface of the heater 92 and a top surface of the fourth dielectric layer 24 ranges from approximately 5000 Å to 10000 Å. A length of the conductive contacts 80a′ and 82a′ ranges from approximately 6000 Å to 12000 Å. The thickness of the heater 92 ranges from approximately 1500 Å to 3000 Å.

Conductive interconnects 89 are formed on the third conductive contacts 83b′ and first conductive contact 80a′ and 82a′. In some embodiments, the conductive interconnects 89 include a material such as Cu or other suitable metals. A dielectric layer 92b is formed on the heater 92. In some embodiments, the dielectric layer 92b includes dielectric materials such as SiN, or other suitable materials.

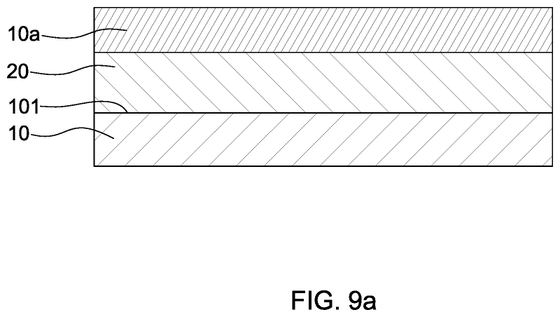

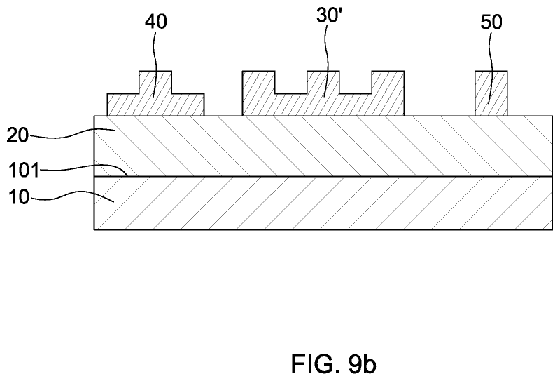

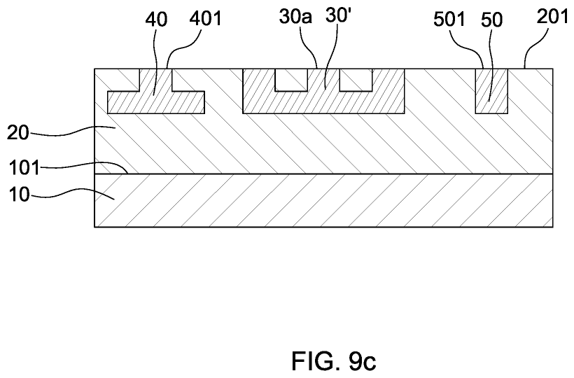

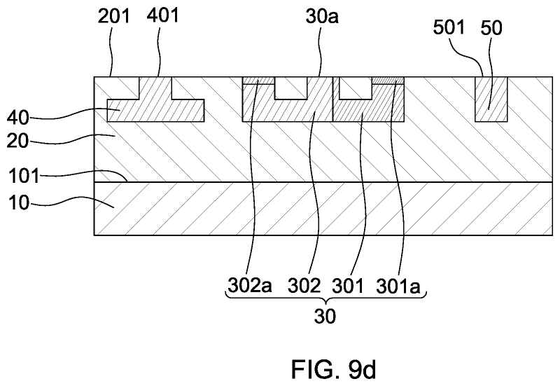

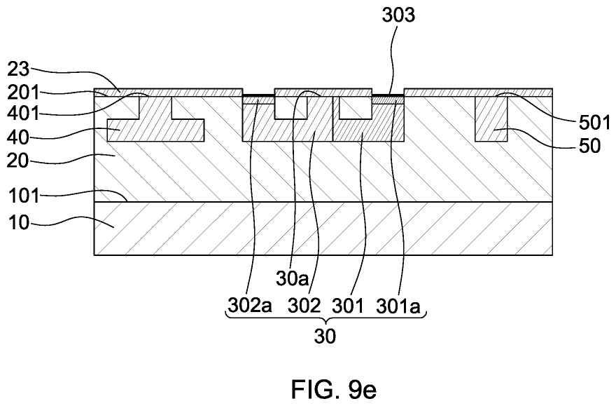

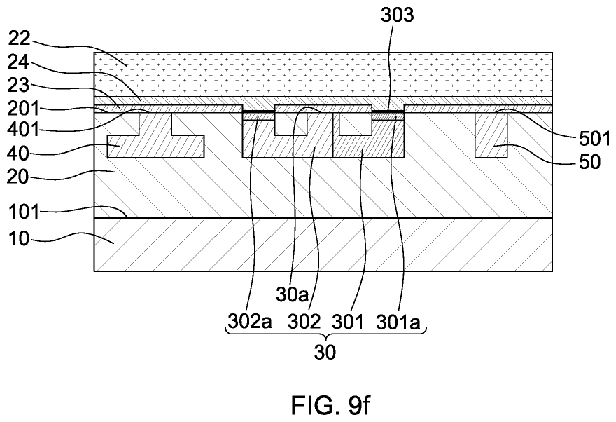

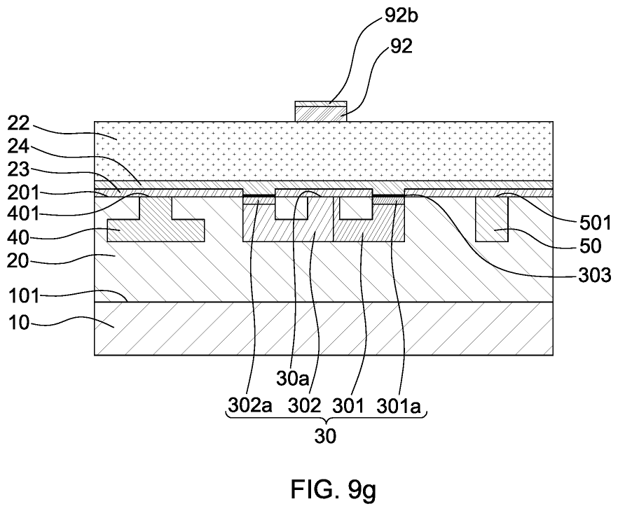

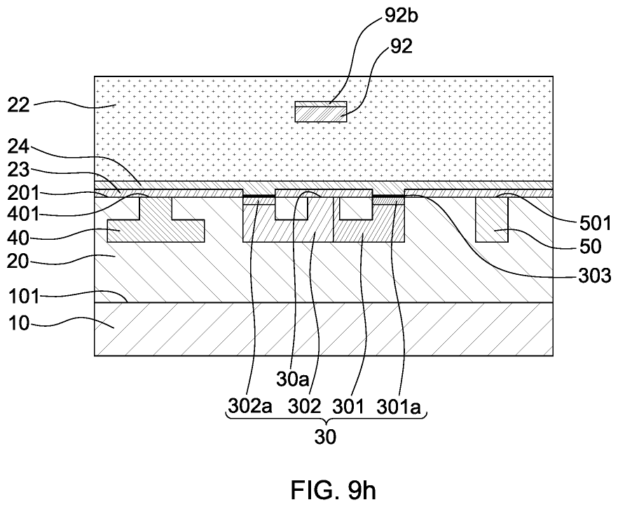

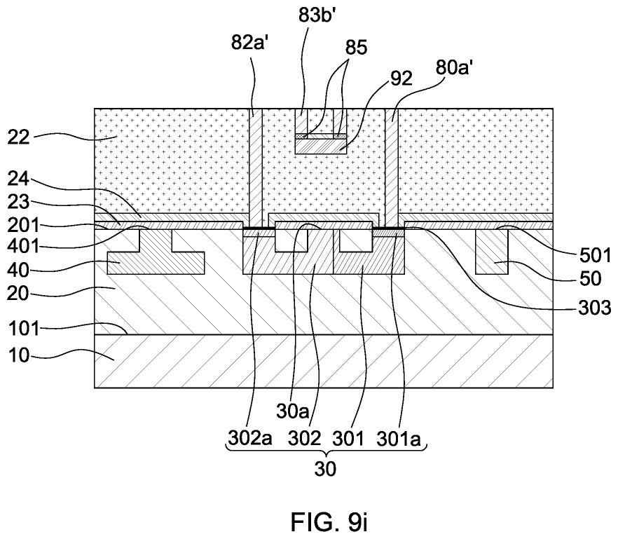

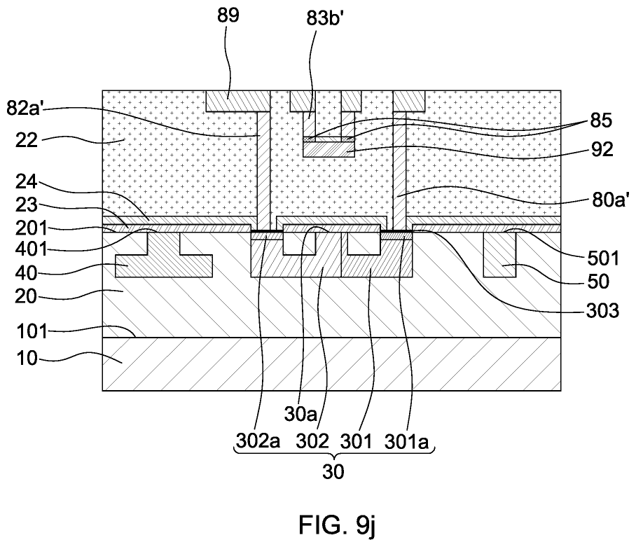

FIGS. 9a, 9b, 9c, 9d, 9e, 9f, 9g, 9h, 9i, and 9j illustrate a method for manufacturing the semiconductor device 8 shown in FIG. 8, in accordance with some embodiments of the present disclosure. Referring to FIG. 9a, a semiconductor substrate 10 is provided. In some embodiments, the semiconductor substrate 10 includes several materials such as silicon, GaAs, germanium, SOI or other suitable semiconductive materials. A first dielectric layer 20 is formed or provided on the top surface 101 of the semiconductor substrate 10. The first dielectric layer 20 includes dielectric materials such as SiO₂, SiN, SiCOH, a spin-on low-k dielectric material such as SiLK™, etc, or other suitable materials. In some embodiments, the thickness of the first dielectric layer 20 ranges from approximately 1.5 μm to 2 μm. A silicon layer 10a is formed or provided on first dielectric layer 20. In some embodiments, the thickness of the silicon layer 10a ranges from approximately 200 nm to 240 nm.

Referring to FIG. 9b, a first waveguide 50, a second waveguide 40, and a silicon structure 30′ are formed by shallow Si etching and/or deep Si etching of the silicon layer 10a. In some embodiments, the first waveguide 50, the second waveguide 40, and the silicon structure 30′ are formed by operations similar to those recited for FIG. 9b.

Referring to FIG. 9c, a material the same as the first dielectric layer 20 is formed on the first dielectric layer 20 to cover the first waveguide 50, second waveguide 40, and silicon structure 30′. The first top surface 201 of the first dielectric layer 20 is coplanar with a second top surface 501 of the first waveguide 50, a third top surface 30a of the silicon structure 30′, and a fourth top surface 401 of the second waveguide 40 the first top surface 201.

Referring to FIG. 9d, the operations of implanting of the impurity dopants are similar to those of FIG. 9d. After implanting, the light modulator 30 is formed. The light modulator 30 includes a n-type doped region 301, a p-type doped region 302, a n-plus doped layer 301a, and a p-plus doped layer 302a.

Referring to FIG. 9e, a third dielectric layer 23 is disposed on the first top surface 201 of the first dielectric layer 20. Formation of the third dielectric layer 23 is similar to that recited for FIG. 9e.

Referring to FIG. 9f, a fourth dielectric layer 24 is formed on the third dielectric layer 23. A portion of the fourth dielectric layer 24 is recessed from the top surface of the third dielectric layer 23 and is disposed in the third dielectric layer 23. In some embodiments, the fourth dielectric layer 24 includes dielectric materials such as SiN, or other suitable materials. The second dielectric layer 22 is disposed on the fourth dielectric layer 24. The second dielectric layer 22 includes dielectric materials such as SiO₂, SiN, SiCOH, a spin-on low-k dielectric material such as SiLK™, etc, or other suitable materials. In some embodiments, the second dielectric layer 22 includes SiO₂.

Referring to FIG. 9g, a heater 92 is formed on the second dielectric layer 22. In some embodiments, the heater 92 includes TiN. A dielectric layer 92b is formed on the heater 92. In some embodiments, the dielectric layer 92b includes dielectric materials such as SiN, SiON, or other suitable materials. The dielectric layer 92b can be an anti-reflection coating (ARC) layer utilized in the formation of the heater 92 during photolithography.

Referring to FIG. 9h, a material the same as the second dielectric layer 22 is formed to cover the heater 92 and dielectric layer 92b.

Referring to FIG. 9i, two recesses above the heater 92 are formed in the second dielectric layer 22, and filled with a seed layer 85. The seed layer 85 is electrically connected to the heater 92. In some embodiments, the seed layer 85 includes Ti. Two recesses above the conductive silicide layer 303 are formed. Next, a metal material (such as W) is filled into the four recesses. After filling, the conductive contacts 80a′, 82a′, and 83a′ are obtained. A distance between a bottom surface of the heater 92 and a top surface of the fourth dielectric layer 24 ranges from approximately 5000 Å to 10000 Å. A length of the conductive contacts 80a′ and 82a′ ranges from approximately 6000 Å to 12000 Å. The thickness of the heater 92 ranges from approximately 1500 Å to 3000 Å.

Referring to FIG. 9j, material the same as the second dielectric layer 22 is formed to cover a top surface of the conductive contacts 80a′, 82a′, and 83b′. Conductive interconnects 89 are formed on the conductive contacts 80a′ and 82a′ and third conductive contacts 83b′. After the conductive interconnects 89 are formed, the semiconductor device 8 shown in FIG. 8 is obtained.

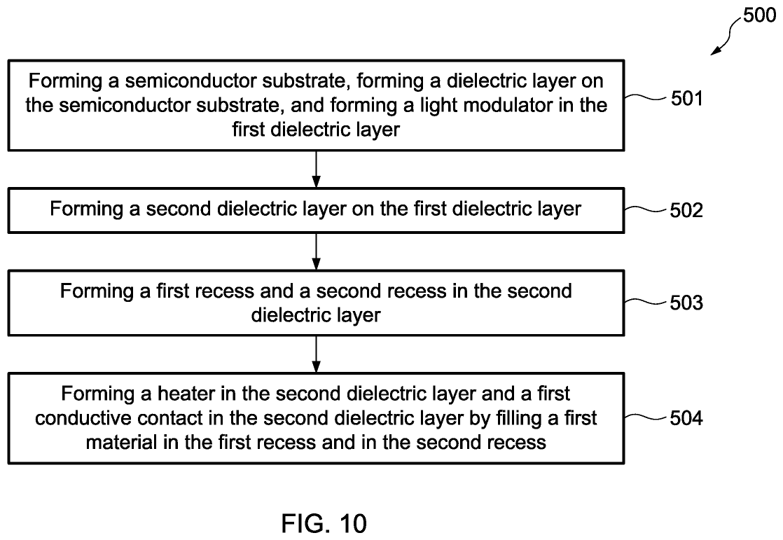

FIG. 10 is a flowchart of an embodiment of a method 500 of manufacturing a semiconductor device 6 in accordance with some embodiments of the present disclosure. The method 500 includes forming a semiconductor substrate 10, forming a dielectric layer 20′ on the semiconductor substrate 10, and forming a light modulator 30 in the first dielectric layer 20 (block 501). The method 500 includes forming a second dielectric layer 22 on the first dielectric layer 20 (block 502). The method 500 includes forming a first recess 77 and a second recess 78 in the second dielectric layer 22 (block 503). The method 500 includes forming a heater 90 in the second dielectric layer 22 and a first conductive contact 80a and 82a in the second dielectric layer 22 by filling a first material in the first recess 77 and in the second recess 78 (block 504).

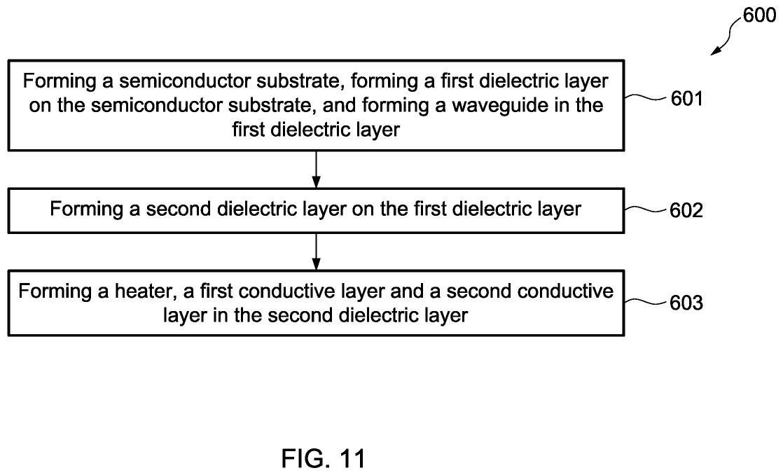

FIG. 11 is a flowchart of an embodiment of a method 600 of manufacturing a semiconductor device 1 in accordance with some embodiments of the present disclosure. The method 600 includes forming a semiconductor substrate 10, forming a dielectric layer 20 on the semiconductor substrate 10, and forming a waveguide 60 in the first dielectric layer 20 (block 601). The method 600 includes forming a second dielectric layer 22 on the first dielectric layer 20 (block 602). The method 600 includes forming a heater 95, a first conductive layer 87, and a second conductive layer 89 in the second dielectric layer 22.

According to some embodiments, a semiconductor device includes a semiconductor substrate, a first dielectric layer, a second dielectric layer, a waveguide, a heater, a first conductive layer, a conductive contact, and a second conductive layer. The first dielectric layer is disposed on the semiconductor substrate. The second dielectric layer is disposed on the first dielectric layer. The waveguide is disposed in the first dielectric layer. The heater is disposed in the second dielectric layer and above the waveguide. The first conductive layer comprises a plurality of first conductive interconnects disposed above the heater. The conductive contact is electrically connected to the heater and disposed between the heater and the first conductive layer. The second conductive layer comprises a plurality of second dummy interconnects disposed above the first conductive layer, wherein the heater is annular from a top view and the second conductive layer includes a clearance zone above the annular heater from the top view. No second dummy interconnect is disposed in the clearance zone from the top view.

According to some embodiments, a semiconductor device includes a semiconductor substrate, a first dielectric layer, a second dielectric layer, an annular waveguide, a strip waveguide, an annular heater, a first conductive layer, and a second conductive layer. The first dielectric layer is disposed on the semiconductor substrate. The second dielectric layer is disposed on the first dielectric layer. The annular waveguide is disposed in the first dielectric layer. The strip waveguide is disposed in the first dielectric layer and adjacent to the annular waveguide. The annular heater is disposed in the second dielectric layer and directly above the annular waveguide. The first conductive layer comprises a plurality of first conductive interconnects disposed above and electrically connected to the annular heater. A portion of the first conductive layer is disposed directly above the annular heater. The second conductive layer comprises a plurality of second dummy interconnects disposed above the first conductive layer. A vertical projection of one of the plurality of second dummy interconnects falls on one of the plurality of first conductive interconnects.

According to some embodiments, a method for manufacturing a semiconductor device comprises forming a semiconductor substrate, forming a first dielectric layer on the semiconductor substrate, forming a waveguide in the first dielectric layer, forming a second dielectric layer on the first dielectric layer, and forming a heater, a first conductive layer, and a second conductive layer in the second dielectric layer; wherein a vertical projection of the second conductive layer falls on one portion of the heater and no second dummy interconnect is directly disposed above the other portion of the heater from the top view.

The methods and features of the present disclosure have been sufficiently described in the foregoing examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods, and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods, or steps. In addition, each claim constitutes a separate embodiment, and the combination of various claims and embodiments are within the scope of the present disclosure.

What is claimed is:

1. A semiconductor device comprising:
a semiconductor substrate;
a first dielectric layer disposed on the semiconductor substrate;
a second dielectric layer disposed on the first dielectric layer;
a waveguide disposed in the first dielectric layer;
a heater disposed in the second dielectric layer and above the waveguide;
a first conductive layer comprising a plurality of first conductive interconnects disposed above the heater;
a conductive contact electrically connected to the heater and disposed between the heater and the first conductive layer;
a second conductive layer comprising a plurality of second dummy interconnects disposed above the first conductive layer, wherein the heater comprises a ring shape from a top view and the second conductive layer includes a clearance zone above the ring shape of the heater from the top view, wherein no second dummy interconnect is disposed in the clearance zone from the top view.

2. The semiconductor device of claim 1, wherein the waveguide comprises a second ring shape being aligned with the ring shape of the heater from the top view.

3. The semiconductor device of claim 2, further comprising a strip waveguide disposed in the first dielectric layer, wherein no second dummy interconnect is disposed directly above the strip waveguide from the top view.

4. The semiconductor device of claim 1, wherein a lateral distance between a second dummy interconnect and a geometric center of the ring shape of the heater from the top view is about 15 micrometers (μm) to 35 μm.

5. The semiconductor device of claim 1, wherein the conductive contact is electrically connected to one of the plurality of first conductive interconnects.

6. The semiconductor device of claim 1, wherein the first conductive layer further comprises a plurality of first dummy interconnects, and wherein each of the plurality of second dummy interconnects is aligned with each of the plurality of first dummy interconnects from the top view, and wherein no second dummy interconnect is directly disposed above the plurality of first conductive interconnects from the top view.

7. The semiconductor device of claim 1, wherein a lateral width of one of the plurality of first conductive interconnects is greater than a lateral width of one of the plurality of second dummy interconnects.

8. The semiconductor device of claim 6, wherein the lateral width of one of the plurality of first conductive interconnects is greater than a lateral width of one of the plurality of first dummy interconnects.

9. The semiconductor device of claim 1, wherein a thickness of the heater ranges from approximately 1500 Å to 3000 Å.

10. A semiconductor device comprising:
a semiconductor substrate;
a first dielectric layer disposed on the semiconductor substrate;
a second dielectric layer disposed on the first dielectric layer;
a ring shape waveguide disposed in the first dielectric layer;
a strip waveguide disposed in the first dielectric layer and adjacent to the ring shape waveguide;
a ring shape heater disposed in the second dielectric layer and directly above the ring shape waveguide;
a first conductive layer comprising a plurality of first conductive interconnects disposed above and electrically connected to the ring shape heater, wherein a portion of the first conductive layer is disposed directly above the ring shape heater; and
a second conductive layer comprising a plurality of second dummy interconnects disposed above the first conductive layer, wherein a vertical projection of one of the plurality of second dummy interconnects falls on one of the plurality of first conductive interconnects.

11. The semiconductor device of claim 10, wherein the ring shape waveguide is aligned with the ring shape heater from the top view.

12. The semiconductor device of claim 10, further comprising a strip waveguide disposed in the first dielectric layer, wherein a vertical projection of the second conductive layer falls on only one portion of the strip waveguide and wherein no second conductive layer is directly disposed above the other portion of the strip waveguide from the top view.

13. The semiconductor device of claim 10, wherein a vertical projection of the second conductive layer falls on a vertical projection of a strip waveguide.

14. The semiconductor device of claim 10, wherein a vertical projection of the second conductive layer falls on a vertical projection of the ring shape heater.

15. The semiconductor device of claim 10, wherein a vertical projection of the second conductive layer falls on only one portion of the ring shape heater and wherein no second conductive layer is directly disposed above the other portion of the ring shape heater from the top view.

16. The semiconductor device of claim 15, wherein there is no second dummy interconnect directly disposed above the other portion of the ring shape heater from the top view.

17. The semiconductor device of claim 10, further comprising a conductive contact electrically connected to the ring shape heater and disposed between the ring shape heater and the first conductive layer, and wherein the first conductive layer further comprises a plurality of first dummy interconnects, and wherein one of the plurality of first dummy interconnects is aligned with a corresponding one of the plurality of second dummy interconnects from a top view.

18. The semiconductor device of claim 10, wherein a thickness of the ring shape heater ranges from approximately 1500 Å to 3000 Å.

19. A method for manufacturing a semiconductor device comprising:
forming a semiconductor substrate;
forming a first dielectric layer on the semiconductor substrate;
forming a waveguide in the first dielectric layer;
forming a second dielectric layer on the first dielectric layer, and
forming a heater, a first conductive layer and a second conductive layer in the second dielectric layer;
wherein a vertical projection of the second conductive layer falls on one portion of the heater and no second dummy interconnect is directly disposed above the other portion of the heater from the top view.

20. The method of claim 19, wherein a distribution density of the second conductive layer directly disposed above the heater from the top view is adjusted based on a parameter of a thermal response of the semiconductor device.
